(19) United States
(12) Patent Application Publication
(10) Pub. No.: US 2011/0220396 A1
(43) Pub. Date: Sep. 15, 2011

(54) WIRING SUBSTRATE AND MANUFACTURING METHOD THEREOF

(75) Inventor: Tomoyuki Abe, Kawasaki (JP)

(73) Assignee: FUJITSU LIMITED, Kawasaki-shi (JP)

(21) Appl. No.: 13/111,257

(22) Filed: May 19, 2011

Related U.S. Application Data
(63) Continuation of application No. PCT/JP2008/003401, filed on Nov. 20, 2008.

(51) Int. Cl. H05K 1/09; H05K 3/46; B05D 5/00; B05D 5/12; B82Y 30/00; B82Y 99/00

(52) U.S. Cl. 174/251; 427/97.1; 977/742; 977/932

(57) ABSTRACT

A wiring substrate includes a substrate containing a carbon material, a first insulating layer formed over the substrate, an interlayer formed over the first insulating layer, the interlayer including a metal plate having a smaller coefficient of thermal expansion than the first insulating layer while having a greater elastic modulus than the first insulating layer, and a second insulating layer formed over the interlayer.

### CROSS-REFERENCE TO RELATED APPLICATION

This is a continuation of International Application No. PCT/JP2008/003401 filed on Nov. 20, 2008, the entire contents of which are incorporated herein by reference.

### FIELD

An aspect of the embodiments discussed herein is directed to a wiring substrate, and a manufacturing method of a wiring substrate.

### BACKGROUND

Electronic components, such as a semiconductor element, and wiring substrates (package substrates), such as a printed circuit board, which are used in electronic apparatuses, are each required to reduce its size. On the other hand, as the number of pins of a semiconductor element is increased, it is desirable to employ a multilayer wiring substrate including multiple wiring layers. As the multilayer wiring substrate described above, for example, a build-up multilayer wiring substrate has been employed in which at least one wire formed by alternately laminating insulating layers and conductive layers. The laminating insulating layers and conductive layers are formed over at least one primary surface of a core substrate.

When a semiconductor element is bare-chip mounted on the build-up multilayer wiring substrate as described above, a glass-epoxy resin board is used as a wiring layer. The coefficient of thermal expansion of the glass-epoxy resin board is approximately 12 ppm/° C. to 20 ppm/° C. On the other hand, the coefficient of thermal expansion of a semiconductor element of silicon (Si) is approximately 3.5 ppm/° C. As described above, the coefficient of thermal expansion of the wiring layer is considerably different from that of the semiconductor element. Hence, when a semiconductor element is bare-chip mounted on the build-up multilayer wiring substrate as described above, a thermal stress, a thermal strain, and the like are generated therebetween. As a result, for example, fatigue breakage and/or disconnection may occur in some cases.

Japanese Examined Patent Application Publication No. 2004-515610 discusses a wiring substrate in which instead of a glass cloth used for a glass epoxy resin board. A base material containing carbon fibers is used for a core substrate, and wiring layers each containing a thermally conductive material is formed at a top and a bottom side of the core substrate.

However, for example, when approximately 40 wiring layers are laminated, and the thickness of the core substrate is 1.2 mm, the total thickness of wiring layers and insulating layers laminated on the surface the core substrate is 6.0 mm to 7.0 mm. Then, the total thickness of the wiring layers and the insulating layers is 5 times to 6 times the thickness of the core substrate. As the number of wiring layers is increased, the ratio of glass epoxy prepregs which insulate and weld between the wiring layers is increased as compared to the ratio of the wiring layers. The coefficient of thermal expansion of the glass epoxy prepreg is generally 10 ppm/° C. to 20 ppm/° C. The coefficient of thermal expansion of the glass epoxy prepreg is high as compared to that of a core substrate containing a carbon fiber material.

Therefore, in bare-chip mounting, the temperature of a semiconductor element and the temperature of a build-up multilayer wiring substrate is increased. Then, the glass epoxy prepreg is more expanded than the semiconductor element. Furthermore, the ratio of the wiring layers containing a thermally conductive material is decreased, compared to the amount of stress deformation of the wiring layers. As the result, the amount of stress deformation generated by thermal expansion of the glass epoxy prepregs becomes dominant. Therefore, a thermal stress and a thermal strain are generated in the wiring substrate. As a result, for example, fatigue breakage and/or disconnection disadvantageously occur.

### SUMMARY

According to an aspect of an embodiment, a wiring substrate includes a substrate containing a carbon material, a first insulating layer formed over the substrate, an interlayer formed over the first insulating layer, the interlayer including a metal plate having a smaller coefficient of thermal expansion than the first insulating layer while having a greater elastic modulus than the first insulating layer, and a second insulating layer formed over the interlayer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating the structure of a wiring substrate according to a first embodiment;

FIGS. 2A to 2D are diagrams illustrating a method for manufacturing the wiring substrate according to the first embodiment;

FIGS. 3A to 3G are diagrams illustrating the method for manufacturing the wiring substrate according to the first embodiment;

FIGS. 4A and 4B are diagrams illustrating the method for manufacturing the wiring substrate according to the first embodiment;

FIGS. 5A and 5B are diagrams illustrating the method for manufacturing the wiring substrate according to the first embodiment;

FIGS. 6A and 6B are diagrams illustrating the method for manufacturing the wiring substrate according to the first embodiment;

FIG. 7 is a table illustrating the coefficient of thermal expansion, the elastic modulus, the amount of thermal deformation, and the amount of stress deformation of each of a core substrate, a prepreg, and a metal plate according to the first embodiment;

FIG. 8 is a diagram illustrating the structure of a wiring substrate according to a second embodiment;

FIGS. 9A to 9D are diagrams illustrating a method for manufacturing the wiring substrate according to the second embodiment;

FIGS. 10A to 10G are diagrams illustrating the method for manufacturing the wiring substrate according to the second embodiment;

FIGS. 11A and 11B are diagrams illustrating the method for manufacturing the wiring substrate according to the second embodiment;

FIGS. 12A and 12B are diagrams illustrating the method for manufacturing the wiring substrate according to the second embodiment; and

FIGS. 13A and 13B are diagrams illustrating the method for manufacturing the wiring substrate according to the second embodiment.

### DESCRIPTION OF EMBODIMENTS

Hereinafter, a first embodiment and a second embodiment may be described. However, the present technique is not limited to these embodiments.

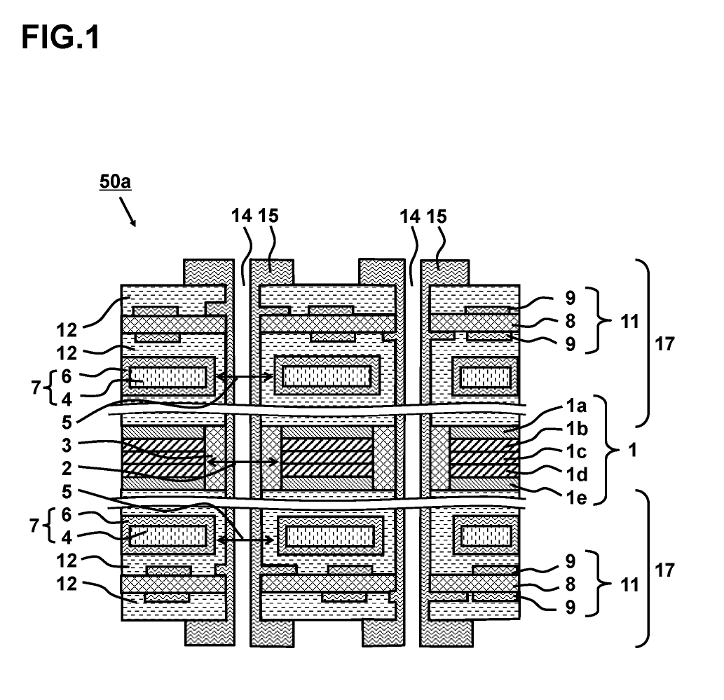

In the first embodiment, FIGS. 1 to 6B are diagrams illustrating in detail the structure of a wiring substrate 50a and a method for manufacturing the same.

FIG. 1 illustrates the structure of the wiring substrate 50a according to the first embodiment.

As illustrated in FIG. 1, the wiring substrate 50a according to the first embodiment includes a core substrate 1, a lower hole 2, an insulating resin 3, a metal plate 4, a lower hole 5, a first wiring layer 6, a first interlayer 7, a glass epoxy layer 8, a second wiring layer 9, a second interlayer 11, a prepreg 12, a through hole 14, a third wiring layer 15, and a wiring layer 17.

Prepregs 1b, 1c, and 1d is each formed by impregnating a conductive carbon fiber material with an epoxy resin composition. Prepregs 1a and 1e is each formed by impregnating glass fibers with a resin material, and copper foils (not illustrated) which form two outer surfaces of the core substrate 1 are laminated. The core substrate 1 is formed in the form of a plate. The total thickness of the core substrate 1 is, for example, 1.0 mm to 2.0 mm.

The number of prepregs forming a carbon fiber-reinforced core portion may be selected in accordance with the thickness, the strength, and the like of the core substrate 1 to be formed. The thickness of each of prepregs 1b, 1c, and 1d is changed by the diameter of carbon fibers to be used. The thickness of each of prepregs 1b, 1c, and 1d is, for example, approximately 100 μm to 300 μm. In addition, besides the carbon fibers, carbon nanotubes, aramid fibers, or poly-p-phenylenebenzobisoxazole (PBO) fibers may also be used.

The prepregs 1b, 1c, and 1d each contain 40 percent to 60 percent by weight of carbon fibers. When a semiconductor element is formed from silicon (Si), the coefficient of thermal expansion thereof is approximately 3.5 ppm/° C. The reason the content of carbon fibers is set as described above is that in conformity with the coefficient of thermal expansion of the semiconductor element. The prepregs 1b, 1c, and 1d may have a coefficient of thermal expansion of 1 ppm/° C. to 2 ppm/° C.

Since the glass fibers are impregnated with a resin, cured prepregs 1a and 1e each have a coefficient of thermal expansion of approximately 12 ppm/° C. to 16 ppm/° C. In addition, the elastic modulus of each of the cured prepregs 1a and 1e is 10 GPa to 30 GPa.

In addition, the lower holes 2 are formed so as to penetrate the core substrate 1. Although the number of the lower holes 2 is determined by wiring layout and the like, in particular, for example, approximately 1,000 lower holes 2 may be formed. It is preferable that the lower holes 2 have a diameter, for example, of 0.3 mm to 1.0 mm and be disposed at intervals, for example, of 0.5 mm to 2.0 mm.

The insulating resin 3 is formed between an inner wall surface of the lower hole 2 and an outer wall surface of the third wiring layer 15. The insulating resin 3 is preferably, for example, an epoxy resin. The insulating resin 3 is preferably has a thickness, for example, of 50 μm to 300 μm. The insulating resin 3 functions as an insulating layer forming the inner wall surface of the lower hole 2 of the core substrate 1 having conductivity. Then, the core substrate 1 may be reliably insulated from the first wiring layer 6 and the second wiring layer 9.

The first interlayer 7 is formed of the metal plate 4 and the first wiring layer 6. The lower holes 5 are formed so as to penetrate the metal plate 4. The first wiring layer 6 is formed so as to cover the top and the bottom surfaces of the metal plate 4 and inner wall surfaces of the lower holes 5. Furthermore, the prepregs 12 are formed in the lower holes 5 of the metal plate 4.

Although the number of the lower holes 5 is determined by wiring layout and the like, in particular, for example, approximately 1,000 lower holes 5 may be formed. It is preferable that the lower holes 5 have a diameter, for example, of 0.3 mm to 1.0 mm and be disposed at intervals, for example, of 0.5 mm to 2.0 mm. In addition, the positions of the lower holes 5 coincide with those of the lower holes 2 when diagramed in plan.

The metal plate 4 preferably has a coefficient of thermal expansion, for example, of 0 ppm/° C. to 5 ppm/° C. The metal plate 4 is preferably formed, for example, to have a thickness of 50 μm to 200 μm. The metal plate 4 is preferably formed, for example, from Invar, Kovar, Alloy 42 (Fe-42% Ni), tungsten, or molybdenum.

The metal plate 4 preferably has an elastic modulus, for example, of 130 GPa to 410 GPa. The elastic modulus of Invar is 140 GPa to 160 GPa. The elastic modulus of Kovar is 130 GPa to 140 GPa. The elastic modulus of Alloy 42 is 140 GPa to 190 GPa. The elastic modulus of tungsten is 403 GPa. The elastic modulus of molybdenum is 327 GPa.

The first wiring layer 6 is preferably formed, for example, from copper (Cu). The first wiring layer 6 is preferably formed to have a thickness, for example, of 20 μm to 40 μm. The first wiring layer 6 is preferably used, for example, as a ground layer or a power source layer.

The second interlayer 11 is formed from the glass epoxy layer 8 and the second wiring layers 9. The glass epoxy layer 8 is preferably formed to have a thickness, for example, of 60 μm to 200 μm.

The second wiring layers 9 are formed so as to sandwich the glass epoxy layer 8 therebetween. The second wiring layer 9 is preferably formed, for example, from copper (Cu). The second wiring layer 9 is preferably formed to have a thickness, for example, of 18 μm to 35 μm. The second wiring layer 9 is preferably used, for example, as a signal layer.

The prepregs 12 are formed so as to fill space between the core substrate 1 and the first interlayer 7. The prepregs 12 are formed so as to fill space between the first interlayer 7 and the second interlayer 11. The prepreg 12 is preferably formed, for example, by impregnating a glass cloth with a thermosetting resin material. The prepreg 12 is preferably formed to have a thickness, for example, of 100 μm to 200 μm. In addition, a prepreg 12 between the inner wall surface of the lower hole 5 and the outer wall surface of the third wiring layer 15 is filled therebetween. The prepreg 12 is filled therebetween when the core substrate 1, the first interlayers 7, and the second interlayers 11 are laminated to each other with the prepregs 12 interposed therebetween. The prepreg 12 is filled therebetween by applying heat and pressure thereto as described later. The prepreg 12 preferably has a coefficient of thermal expansion of 10 ppm/° C. to 20 ppm/° C. In addition, the elastic modulus of a cured prepreg 12 is 10 GPa to 30 GPa.

In addition, the first interlayer 7 and the second interlayer 11 are repeatedly laminated in this order with the prepregs 12 interposed therebetween on each of the two surfaces of the core substrate 1 to form 40 layers. The wiring layer 17 is a layer formed by laminating the first interlayers 7, the second interlayers 11, and the prepregs 12. In the first embodiment, for example, the thickness of the core substrate 1 is 1.2 mm. Then, the wiring layer 17 including the first interlayers 7 and the second interlayers 11 laminated over one side surface of the core substrate 1 has a thickness, for example, of 6.0 mm to 7.0 mm. That is, the thickness of the wiring layer 17 is approximately 5 times to 6 times the thickness of the core substrate 1.

The through holes 14 are formed so as to penetrate the core substrate 1, the first interlayers 7, the second interlayers 11, and the prepregs 12. The through hole 14 is formed approximately concentric with the lower hole 2 of the core substrate 1 and the lower hole 5 of the first interlayer 7. The through hole 14 is preferably formed to have a diameter smaller than a diameter of the lower hole 2 and a diameter of the lower hole 5. The through hole 14 is preferably formed to have a diameter, for example, of 0.1 μm to 0.4 μm.

The third wiring layer 15 is formed along an approximately entire inner wall surface of a penetrating hole 14a along the inner wall surface of the insulating resin 3 of the core substrate 1. The third wiring layer 15 is formed along the prepregs 12, the first interlayers 7, and the second interlayers 11 and the through hole 14 over the prepregs 12. The third wiring layer 15 formed from copper (Cu) by a plating treatment.

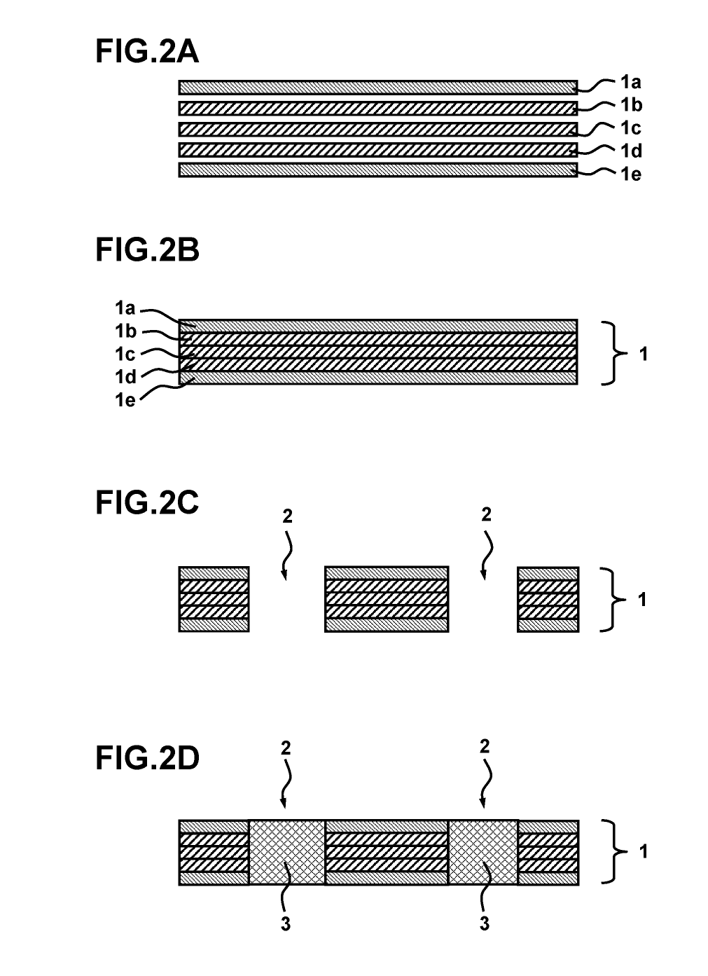

FIGS. 2A to 6B illustrate a process for manufacturing the wiring substrate 50a according to the first embodiment.

FIG. 2A illustrates the state in which the prepregs 1b, 1c, and 1d are formed by impregnating carbon fibers with a resin material (polymer material). Then, the prepregs 1a and 1e are formed by impregnating glass fibers with a resin material. The copper foils (not illustrated) forming the two outer surfaces of the core substrate 1 are laminated and aligned. The prepregs 1a, 1b, 1c, 1d, and 1e and the copper foils are formed to form the core substrate 1.

The prepregs 1b, 1c, and 1d each preferably contain 40 percent to 60 percent by weight of carbon fibers. When the semiconductor element is formed from silicon (Si), the coefficient of thermal expansion thereof is approximately 3.5 ppm/° C. When the content of carbon fibers in the prepregs 1b, 1c, and 1d is less than 40 percent by weight, the coefficient of thermal expansion of each of the prepregs 1b, 1c, and 1d becomes higher than that of silicon. On the other hand, when the content of carbon fibers in the prepregs 1b, 1c, and 1d is more than 60 percent by weight, molding of the prepregs 1b, 1c, and 1d becomes difficult.

As the carbon fiber material, for example, a carbon fiber cloth, a carbon fiber mesh, or a carbon fiber nonwoven cloth may be used. Then, the carbon fiber cloth is formed such that carbon fiber yarns, which are bundled carbon fibers. The carbon fiber cloth is woven and is oriented so as to spread along a surface spreading direction. An inorganic filler, such as an alumina filler, an aluminum nitride filler, or a silica filler, is mixed with an epoxy resin composition which contains a carbon fiber material so as to decrease the coefficient of thermal expansion of the composition. However, as a conductive material contained in the core substrate 1, besides the above carbon fibers, carbon nanotubes may also be used.

In the epoxy resin composition containing carbon fibers, 10 percent to 45 percent by weight of a silica filler is preferably contained with respect to the total composition. When the content of the silica filler in the total composition is less than 10 percent by weight, it becomes difficult to ensure burning resistance of the epoxy resin composition. On the other hand, if the content of the silica filler in the total composition is more than 45 percent by weight, the moldability of the epoxy resin composition is degraded.

The prepreg 1a is formed between one copper foil (not illustrated) and a laminate formed of the prepregs 1b, 1c, and 1d, and the prepreg 1e is formed between the other copper foil (not illustrated) and the above laminate. In this embodiment, a woven cloth of glass fibers is impregnated with an epoxy resin. Then, the epoxy resin is then dried. As the result, the prepregs 1a and 1b in a B stage are prepared. The prepregs 1a and 1e each have a thickness of approximately 100 μm to 200 μm.

The reasons the prepregs 1a and 1e each contain glass fibers are to prevent the strength of the core substrate 1 from decreasing and to allow the core substrate 1 to have a lower coefficient of thermal expansion.

FIG. 2B is a diagram illustrating a step of applying heat and pressure in the state in which the copper foils (not illustrated) are laminated over the surfaces of the respective prepregs 1a and 1e. The respective prepregs 1a and 1e are formed over two surfaces of the laminate formed of the prepreg 1b, 1c, and 1d, the prepregs 1a to 1d. The resin contained in the prepregs 1a, 1b, 1c, 1d, and 1e are heat-cured, and the plate-shaped core substrate 1 is formed. The core substrate 1 is integrally formed in such a way that the copper foils are adhered to the two surfaces of the laminate integrally formed from the prepregs 1b, 1c, and 1d with the respective prepregs 1a and 1e interposed therebetween. The core substrate 1 thus formed has, in a temperature range of 25° C. to 200° C., average coefficients of thermal expansion of 2 ppm/° C. and 80 ppm/° C. in a plane direction and a thickness direction, respectively.

FIG. 2C is a diagram illustrating a step of forming the lower holes 2 in the core substrate 1 by drill machining. The diameter of the lower hole 2 is preferably, for example, 0.8 mm to 1.0 mm. In addition, the lower holes 2 are preferably formed, for example, at intervals of 1.0 mm to 2.0 mm. When these lower holes 2 are formed, since a silica filler (not illustrated) is also removed from the inner wall surface of the lower hole 2, irregularity is generated.

FIG. 2D is a diagram illustrating the state in which, after the inner wall surface of each lower hole 2 of the core substrate 1 is covered with a plating layer (not illustrated), the lower holes 2 are filled with the insulating resin 3. When being filled in each lower hole 2, the insulating resin 3 is firmly buried therein since the irregularity present over the inner wall surface of the lower hole 2 functions as an anchor.

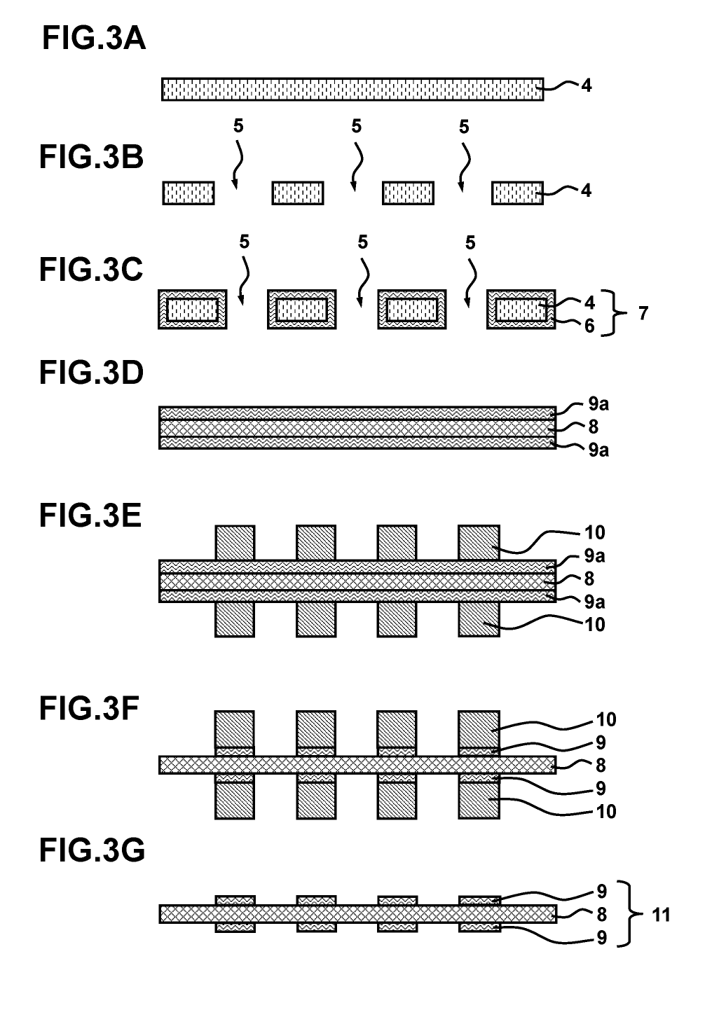

FIG. 3A is a diagram illustrating a step of preparing the metal plate 4 forming the first interlayer 7.

FIG. 3B is a diagram illustrating a step of forming the lower holes 5 in the metal plate 4 by drill machining. It is preferable that the lower holes 5 have a diameter, for example, of 0.8 mm to 1.0 mm and be disposed at intervals, for example, of 1.0 mm to 2.0 mm.

FIG. 3C is a diagram illustrating a step of forming the first wiring layer 6 over the surfaces of the metal plate 4 and the inner wall surfaces of the lower holes 5. As illustrated in FIG. 3C, after the lower holes 5 are formed in the metal plate 4, electroless copper plating and electrolytic copper plating are performed over the metal plate 4. Therefore, the surfaces of the metal plate 4 and the inner wall surfaces of the lower holes 5 are covered with the first wiring layer 6. The first interlayer 7 is formed by the steps as described above.

FIG. 3D is a diagram illustrating a step of preparing a laminate of the glass epoxy layer 8 and conductive layers 9a to form the second interlayer 11. The conductive layers 9a are formed so as to sandwich the glass epoxy layer 8.

FIG. 3E is a diagram illustrating a step of, after a dry film resist (photoresist) (not illustrated) is laminated over the surface of each conductive layer 9a, performing exposure and development over the dry film resist. By the step described above, a resist pattern 10 is formed over each portion at which the second wiring layer 9 is to be formed.

FIG. 3F is a diagram illustrating a step of etching each conductive layer 9a by using the resist pattern 10 as a mask. By this etching step, the second wiring layer 9 is formed under the resist pattern 10.

FIG. 3G is a diagram illustrating a step of, after the step illustrated in FIG. 3F is performed, removing the resist pattern 10 formed over each second wiring layer 9. By this step of removing the resist pattern 10, the second wiring layer 9 is exposed at each surface of the glass epoxy layer 8. Then, the second interlayer 11 is formed.

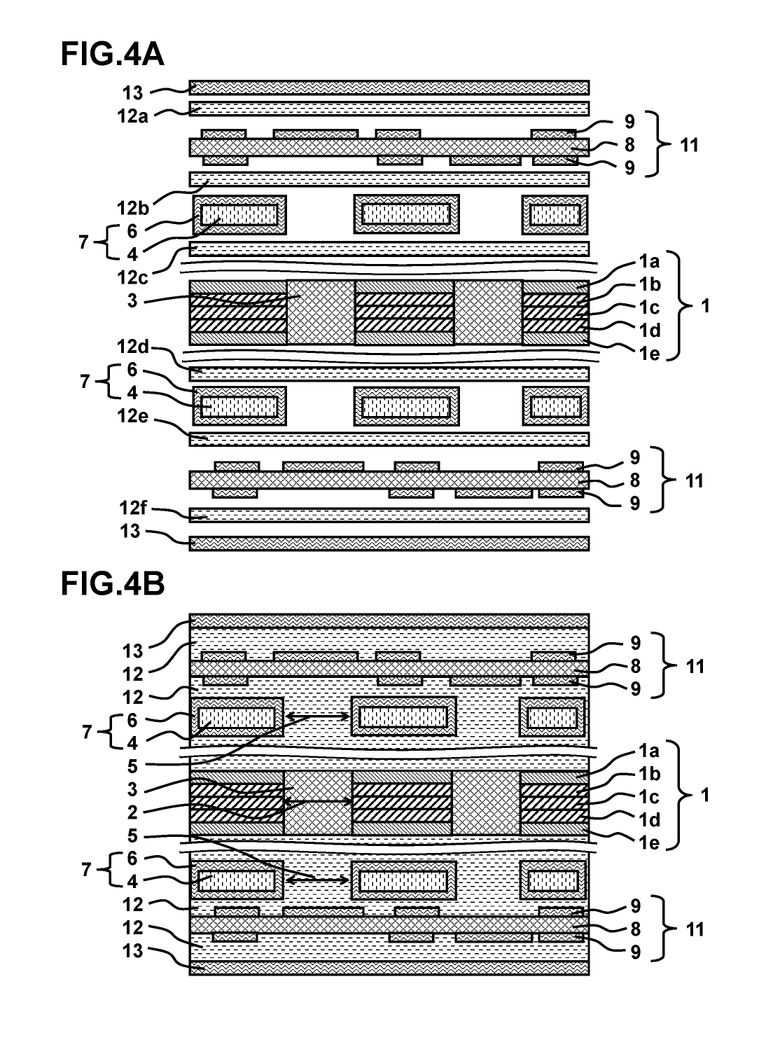

FIG. 4A is a diagram illustrating the state in which a metal foil 13, a prepreg 12a, the second interlayer 11, a prepreg 12b, the first interlayer 7, a prepreg 12c, the core substrate 1, a prepreg 12d, the first interlayer 7, a prepreg 12e, the second interlayer 11, a prepreg 12f, and a metal foil 13 are arranged in this order. The prepregs 12a to 12f are each preferably formed, for example, by impregnating a glass cloth with a thermosetting resin material, such as an epoxy resin. The metal foil 13 is preferably formed from copper (Cu).

FIG. 4B is a diagram illustrating a step of forming a laminate including the core substrate 1, the first interlayers 7, the second interlayers 11, and the metal foils 13 laminated with the respective prepregs 12 interposed therebetween. The first interlayers 7 each have the lower holes 5. When the prepregs 12a, 12b, 12c, 12d, 12e, and 12f illustrated in FIG. 4A are processed by a heat treatment, cured prepregs 12 illustrated in FIG. 4B are obtained. By the step described above, the laminate is formed which includes the core substrate 1, the first interlayers 7, the second interlayers 11, and the metal foils 13 laminated with the respective prepregs 12 interposed therebetween. The lower holes 5 formed beforehand in the first interlayer 7 are filled with the prepregs 12.

In this case, the lower holes 2 of the core substrate 1 are preferably arranged concentrically with the lower holes 5 of each first interlayer 7. The reason for this is to prevent the penetrating holes 14a from penetrating the core substrate 1 and the first interlayers 7, each of which is a conduction member, when the penetrating holes 14a are formed.

Application of pressure to each member is carried out by a vacuum press (not illustrated). A temperature for pressure application is preferably, for example, 170° C. to 220° C. The prepregs 12a to 12f in an uncured state are formed between the layers and are then cured into the prepregs 12 by application of heat and pressure. Then, the core substrate 1, the first interlayers 7, and the second interlayers 11 are laminated to each other with the respective prepregs 12 interposed therebetween so as to be electrically insulated from each other.

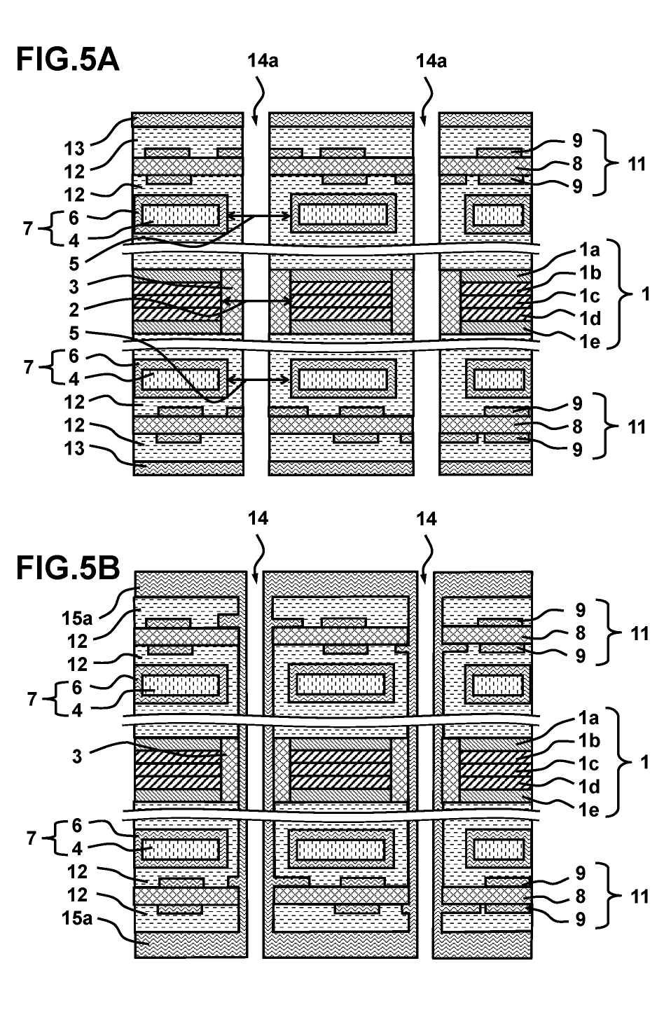

FIG. 5A is a diagram illustrating a step of forming the penetrating holes 14a for forming the through holes 14 in the core substrate 1, the first interlayers 7, the second interlayers 11, and the prepregs 12 laminated to each other. The penetrating holes 14a are preferably formed by penetrating the first interlayers 7, the second interlayers 11, the prepregs 12, and the core substrate 1 in a thickness direction using drill machining. The penetrating holes 14a may be concentric with the lower holes 2 of the core substrate 1 and the lower holes 5. The penetrating hole 14a is preferably formed to have a diameter, for example, of 0.2 μm to 0.4 μm. The penetrating hole 14a is preferably formed so as to have a smaller diameter than that of the lower hole 2 of the core substrate 1 and that of the lower hole 5 of the first interlayer 7. At a portion at which the penetrating hole 14a penetrates the core substrate 1, the insulating resin 3 is exposed to the inner wall surface of the penetrating hole 14a. In addition, at a portion at which the penetrating hole 14a penetrates the first interlayer 7, the prepregs 12 are exposed to the inner wall surface of the penetrating hole 14a.

FIG. 5B illustrates the state in which after the penetrating holes 14a are formed, electroless copper plating and electrolytic copper plating are performed over the substrate. Then, the through holes 14 are formed along the inner surfaces of the penetrating holes 14a. By the electroless copper plating, an electroless copper layer is formed over the entire inner surfaces of the penetrating holes 14a and the entire surfaces of the substrate. By performing the electrolytic copper plating using this electroless copper film as a plating power supply layer, a third plating layer 15a is formed to cover the entire inner wall surfaces of the penetrating holes 14a. The third plating layer 15a is formed to cover the entire surfaces of the substrate. The third plating layer 15a formed over the inner wall surface of the penetrating hole 14a forms the through hole 14 which electrically connects between circuit patterns over the front and the rear surfaces of the substrate.

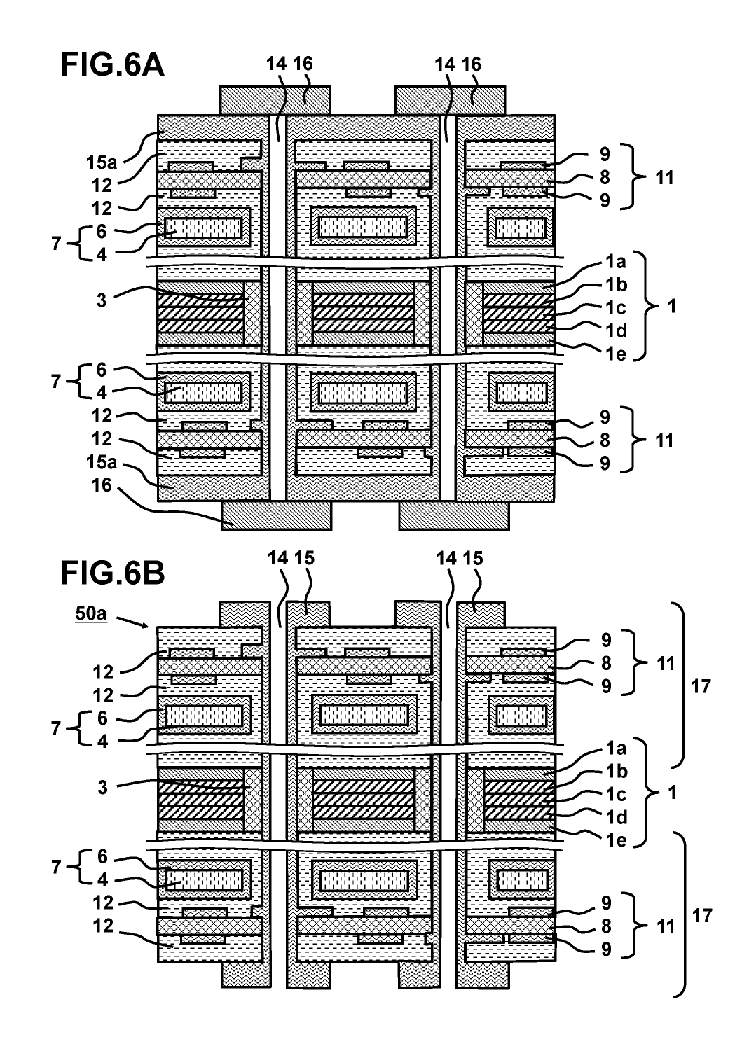

FIG. 6A is a diagram illustrating a step of, after a dry film resist (photoresist) (not illustrated) is laminated over the surface of the third plating layer 15a adhered over each surface of the substrate, performing exposure and development over the dry film resist. As illustrated in FIG. 6A, resist patterns 16 are formed over portions at which the third wiring layers 15 are to be formed.

FIG. 6B is a diagram illustrating the state in which the third plating layer 15a located at the portion at which the resist pattern 16 is not formed is etched off and the resist pattern 16 is then peeled off. As illustrated in FIG. 6B, the third wiring layers 15 are formed by etching the third plating layer 15a. Subsequently, the third wiring layers 15 are exposed at the surfaces of the substrate by peeling off the resist pattern 16 formed over the third wiring layers 15. Through the steps described above, the wiring substrate 50a is formed including the core substrate 1 and the wiring layers 17 each formed by laminating the first interlayers 7, the second interlayers 11, and the prepregs 12.

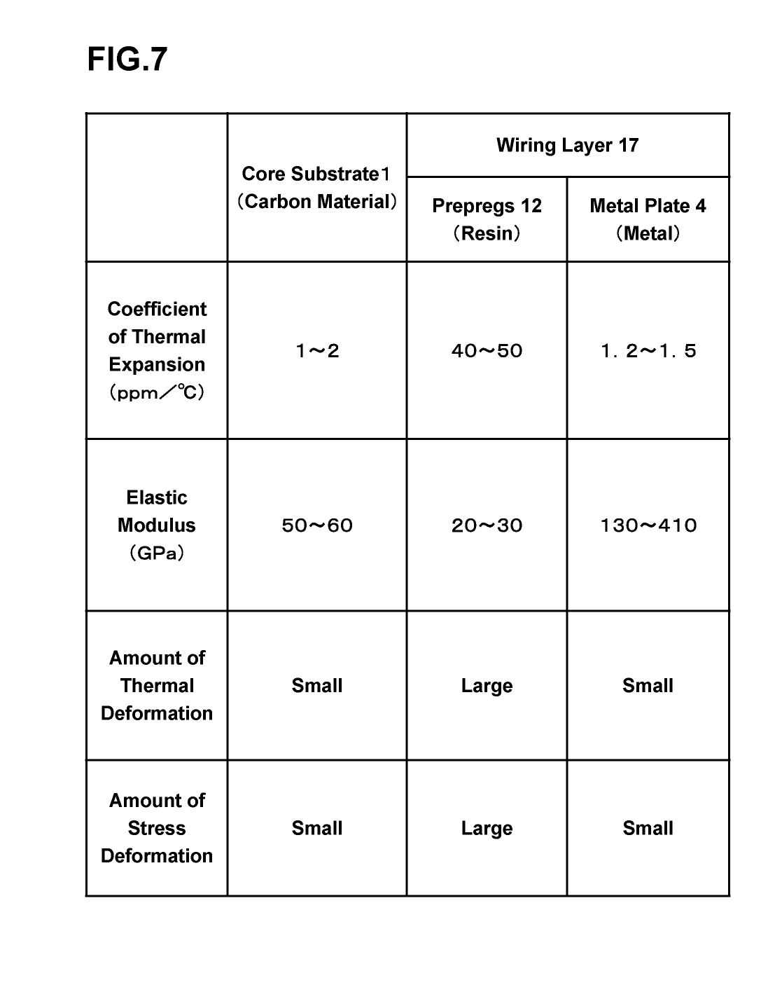

FIG. 7 is a table illustrating the coefficient of thermal expansion, the elastic modulus, the amount of thermal deformation, and the amount of stress deformation of each of the core substrate 1, the prepreg 12, and the metal plate 4 of the first interlayer 7 according to the first embodiment.

As illustrated in FIG. 7, the coefficient of thermal expansion of the core substrate 1 is 1 ppm/° C. to 2 ppm/° C. The coefficient of thermal expansion of the prepreg 12 is 10 ppm/° C. to 20 ppm/° C. The coefficient of thermal expansion of the metal plate 4 is 0 ppm/° C. to 5 ppm/° C. The elastic modulus of the core substrate 1 is 50 GPa to 60 GPa. The elastic modulus of the prepreg 12 is 10 GPa to 30 GPa. The elastic modulus of the metal plate 4 is 130 GPa to 410 GPa.

When a semiconductor element is bare-chip mounted over the wiring substrate 50a, the core substrate 1, the metal plate 4, and the prepreg 12 thereof are heated.

As illustrated in FIG. 7, since the core substrate 1 has a low coefficient of thermal expansion as compared to that of the prepreg 12, the amount of thermal deformation is small. In addition, since the elastic modulus of the core substrate 1 is high as compared to that of the prepreg 12, even if a stress generated by elongation of the wiring layer 17 is applied to the core substrate 1, the amount of stress deformation thereof is small.

In addition, since the prepreg 12 has a high coefficient of thermal expansion as compared to that of the core substrate 1, the amount of thermal deformation becomes large. Since the prepreg 12 has a low elastic modulus as compared to that of the core substrate 1, when a stress generated by elongation of the metal plate 4 is applied to the prepreg 12, the amount of stress deformation thereof is increased. However, in the wiring layer 17, the metal plate 4 is tightly adhered to the prepregs 12 with the first wiring layers 6 interposed therebetween. Since the metal plate 4 has a low coefficient of thermal expansion as compared to that of the prepreg 12, the amount of thermal deformation is small. On the other hand, since the metal plate 4 has a high elastic modulus as compared to that of the prepreg 12, the amount of stress deformation is small.

Accordingly, it is found that although the amount of thermal deformation of the metal plate 4 is small, the amount of thermal deformation of the prepreg 12 is. Therefore, by the change in the amount of displacement caused by thermal expansion of the prepregs 12, an elongation stress is applied to the metal plate 4 through the first wiring layer 6. However, since the elastic modulus of the metal plate 4 is high, even if the elongation stress from the prepreg 12 is applied to the metal plate 4, the amount of deformation thereof is small. Accordingly, the amount of displacement of the prepreg 12 tightly adhered to the metal plate 4 through the first wiring layer 6 is reduced. Hence, the amount of displacement caused by thermal expansion of the wiring layer 17 formed by laminating the metal plates 4 and the prepregs 12 is reduced. As a result, fatigue breakage and/or disconnection of the wiring substrate 50a caused by a thermal stress and a thermal strain, which are generated when a semiconductor element is bare-chip mounted over the wiring substrate 50a, may be suppressed.

According to the wiring substrate 50a of the first embodiment, even if the total number of layers of the wiring layer 17 is increased, the amount of displacement caused by thermal expansion of the prepregs 12 may be reduced by the metal plate 4 which forms the first interlayer 7. Therefore, the amount of displacement caused by thermal expansion of the wiring substrate 50a formed by laminating the wiring layers 17 with the core substrate 1 containing a carbon material is reduced. As a result, fatigue breakage and/or disconnection of the wiring substrate 50a caused by a thermal stress and a thermal strain, which are generated when a semiconductor element is bare-chip mounted over the wiring substrate 50a, may be suppressed.

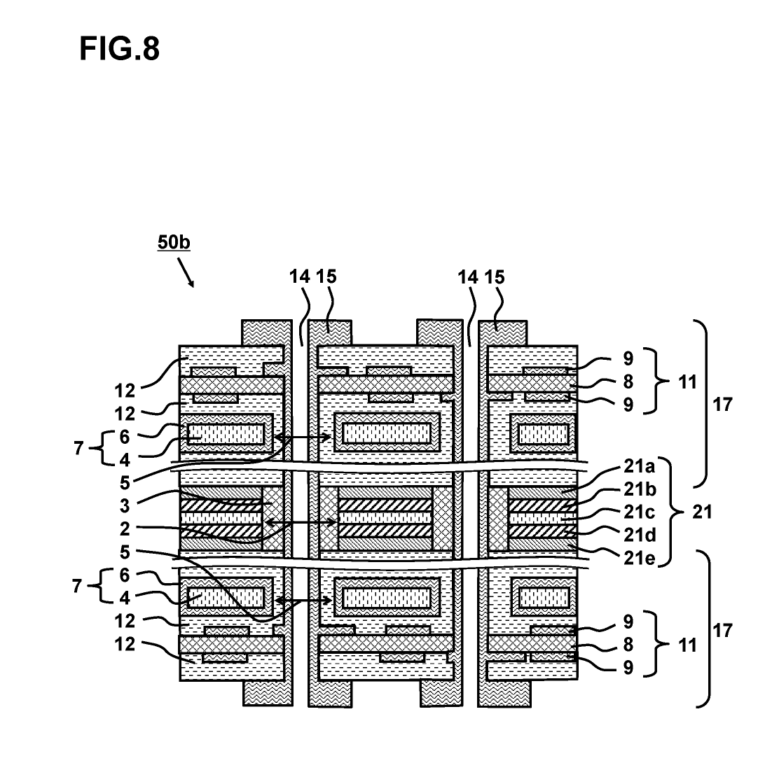

In the second embodiment, FIG. 8 to FIG. 13B are diagrams illustrating in detail the structure of a wiring substrate 50b and a method for manufacturing the same. In addition, in the second embodiment, the same or similar constituent elements as or to those described in the first embodiment are designated by the same reference numerals as those in the first embodiment, and a description may be omitted.

FIG. 8 is a diagram illustrating the structure of the wiring substrate 50b according to the second embodiment.

As illustrated in FIG. 8, the wiring substrate 50b according to the second embodiment includes a core substrate 21, a lower hole 2, an insulating resin 3, a metal plate 4, a lower hole 5, a first wiring layer 6, a first interlayer 7, a glass epoxy layer 8, a second wiring layer 9, a second interlayer 11, a prepreg 12, a through hole 14, a third wiring layer 15, and a wiring layer 17.

The core substrate 21 in the form of a plate is formed as follows. At first, a metal plate 21c is disposed at the center. Then, prepregs 21b and 21d, each of which is formed by impregnating a conductive carbon fiber material with an epoxy resin composition, are laminated so as to sandwich the metal plate 21c. Subsequently, prepreg 21a is laminated between the prepreg 21b and a copper foil (not illustrated), and a prepreg 21e is laminated between the prepreg 21d and a copper foil (not illustrated). The total thickness of the core substrate 21 is, for example, 1.0 mm to 2.0 mm.

The metal plate 21c preferably has a coefficient of thermal expansion, for example, of 0 ppm/° C. to 5 ppm/° C. The metal plate 21c is preferably formed to have a thickness, for example, of 500 μm to 2,000 μm. The metal plate 21c is preferably formed, for example, from Invar, Kovar, Alloy 42 (Fe-42% Ni), tungsten, or molybdenum.

The metal plate 21c preferably has an elastic modulus, for example, of 130 GPa to 410 GPa. The elastic modulus of Invar is 140 GPa to 160 GPa. The elastic modulus of Kovar is 130 GPa to 140 GPa. The elastic modulus of Alloy 42 is 140 GPa to 190 GPa. The elastic modulus of tungsten is 403 GPa. The elastic modulus of molybdenum is 327 GPa.

The prepregs 21b and 21d each function as a carbon fiber reinforced core portion. The case in which the two prepregs 21b and 21d are laminated to each other is illustrated in the figure by way of example. The number of prepregs forming the carbon fiber reinforced core portion may be appropriately selected in accordance with the thickness, the strength, and the like of the core substrate 21 to be formed. Although the thickness of each of the prepregs 21b and 21d is changed by the diameter of carbon fibers to be used, the thickness is, for example, approximately 100 μm to 300 μm. The prepregs 21b and 21d each contain 40 percent to 60 percent by weight of carbon fibers. When the semiconductor element is formed from silicon (Si), the coefficient of thermal expansion thereof is approximately 3.5 ppm/° C. The reason the content of carbon fibers is set as described above is that in conformity with the coefficient of thermal expansion of the semiconductor element. The prepregs 21b and 21d may have a coefficient of thermal expansion of 1 ppm/° C. to 2 ppm/° C.

In addition, as in the case of the first embodiment, the lower holes 2 are formed to penetrate the core substrate 21. Although the number of the lower holes 2 is determined by wiring layout and the like, in particular, for example, approximately 1,000 lower holes 2 may be formed. It is preferable that the lower holed 2 have a diameter, for example, of 0.3 mm to 1.0 mm and be disposed at intervals, for example, of 0.5 mm to 2.0 mm.

In addition, as in the case of the first embodiment, the copper foils (not illustrated) are formed to form the outer surfaces of the core substrate 21. The copper foils are each formed, for example, to protect the core substrate 21, to function as a plating power supply layer when plating is performed over the core substrate 21. The copper foils are each formed to improve adhesion between the core substrate 21 and the wiring layers when the wiring layers are laminated over the two surfaces of the core substrate 21 for the formation of the wiring substrate 50b. The thickness of the copper foil is preferably, for example, approximately 15 μm to 35 μm.

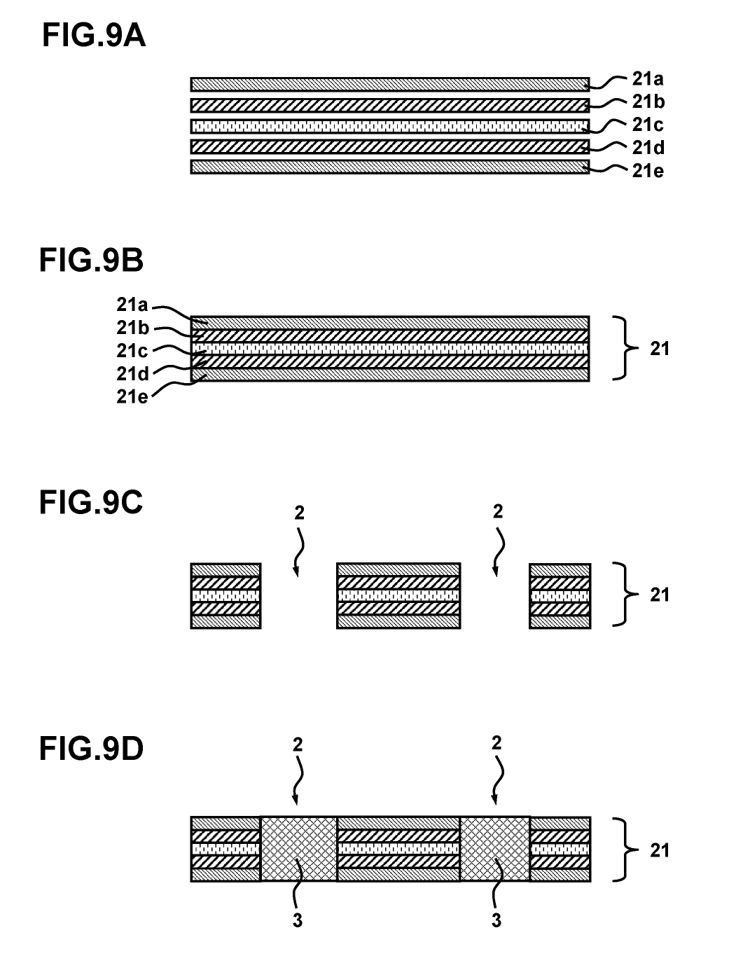

FIGS. 9A to 13B are diagrams illustrating a process for manufacturing the wiring substrate 50b according to the second embodiment.

FIG. 9A illustrates the state in which the prepregs 21b and 21d are formed by impregnating carbon fibers with a resin material (polymer material). The prepregs 21a and 21e are formed by impregnating glass fibers with a resin material. The copper foils (not illustrated) are used to cover the surface of the prepreg 21a and the surface of the prepreg 21e. The metal plate 21c is positioned at the center of the core substrate 21. The prepregs 21a, 21b, 21d and 21e and the metal plate 21c are aligned so as to form the core substrate 21.

The prepregs 21b and 21d used in this embodiment are each in a B stage prepared by impregnating a cloth formed of long carbon fibers with an epoxy resin, followed by performing drying. Although the thickness of each of the prepregs 21b and 21d is changed dependent on the diameter of carbon fibers to be used, for example, the thickness is approximately 100 μm to 300 μm.

As in the case of the first embodiment, as the carbon fiber material, for example, a carbon fiber cloth, a carbon fiber mesh, or a carbon fiber nonwoven cloth may be used. The carbon fiber cloth is formed such that carbon fiber yarns, which are bundled carbon fibers, are woven and are oriented so as to spread along a surface spreading direction.

As in the case of the first embodiment, the epoxy resin composition containing carbon fibers preferably contains 10 percent to 45 percent by weight of a silica filler with respect to the entire composition.

FIG. 9B is a diagram illustrating a step of applying heat and pressure in the state in which the prepregs 21a, 21b, 21d and 21e, the metal plate 21c, and the copper foils (not illustrated) are laminated as illustrated in FIG. 9A. As illustrated in FIG. 9B, the resin contained in the prepregs 21a, 21b, 21d, and 21e are heat-cured, and the plate-shaped core substrate 21 is formed. The core substrate 21 is integrally formed such that the copper foils are adhered to two surfaces of a laminate integrally formed of the prepregs 21b and 21d and the metal plate 21c with the prepregs 21a and 21e interposed therebetween. The core substrate 21 thus formed has, in a temperature range of 25° C. to 200° C., average coefficients of thermal expansion of 2 ppm/° C. and 80 ppm/° C. in a plane direction and a thickness direction, respectively.

FIG. 9C is a diagram illustrating a step of forming the lower holes 2 in the core substrate 21 by drill machining. The diameter of the lower hole 2 is preferably, for example, 0.8 mm to 1.0 mm. In addition, the lower holes 2 are preferably formed, for example, at intervals of 1.0 mm to 2.0 mm. When these lower holes 2 are formed, since a silica filler (not illustrated) is also removed from an inner wall surface of the lower hole 2, irregularity is generated.

As in the case illustrated in FIG. 2D, FIG. 9D is a diagram illustrating a step of, after the inner wall surface of each lower hole 2 of the core substrate 21 is covered with a plating layer (not illustrated), the lower holes 2 are filled with the insulating resin 3.

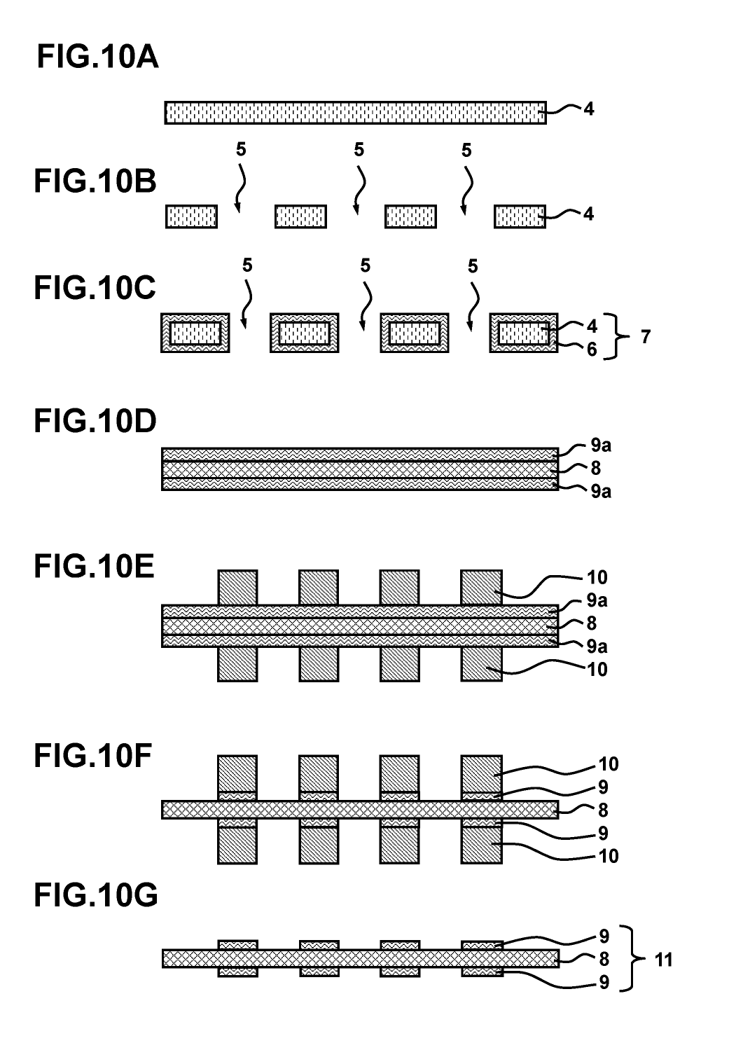

As in the case illustrated in FIG. 3A, FIG. 10A is a diagram illustrating a step of preparing the metal plate 4 forming the first interlayer 7 which may be described later.

As in the case illustrated in FIG. 3B, FIG. 10B is a diagram illustrating a step of forming the lower holes 5 in the metal plate 4 by drill machining.

As in the case illustrated in FIG. 3C, FIG. 10C is a diagram illustrating a step of forming the first wiring layer 6 over the surfaces of the metal plate 4 and inner wall surfaces of the lower holes 5. By the steps described above, the first interlayer 7 is formed.

As in the case illustrated in FIG. 3D, FIG. 10D is a diagram illustrating a step of preparing a laminate of the glass epoxy layer 8 and conductive layers 9a to form the second interlayer 11 which may be described later.

As in the case illustrated in FIG. 3E, FIG. 10E is a diagram illustrating a step of, after a dry film resist (photoresist) (not illustrated) is laminated over the surface of each conductive layer 9a, performing exposure and development. By the step described above, a resist pattern 10 is formed over each portion at which the second wiring layer 9 is to be formed.

As in the case illustrated in FIG. 3F, FIG. 10F is a diagram illustrating a step of forming the second wiring layer 9 by etching the conductive layer 9a using the resist pattern 10 as a mask.

As in the case illustrated in FIG. 3G, FIG. 10G is a diagram illustrating a step of, after the step illustrated in FIG. 10F is performed, removing the resist pattern 10 formed over the second wiring layer 9. By this step of removing the resist pattern 10, the second wiring layer 9 is exposed at each surface of the glass epoxy layer 8, so that the second interlayer 11 is formed.

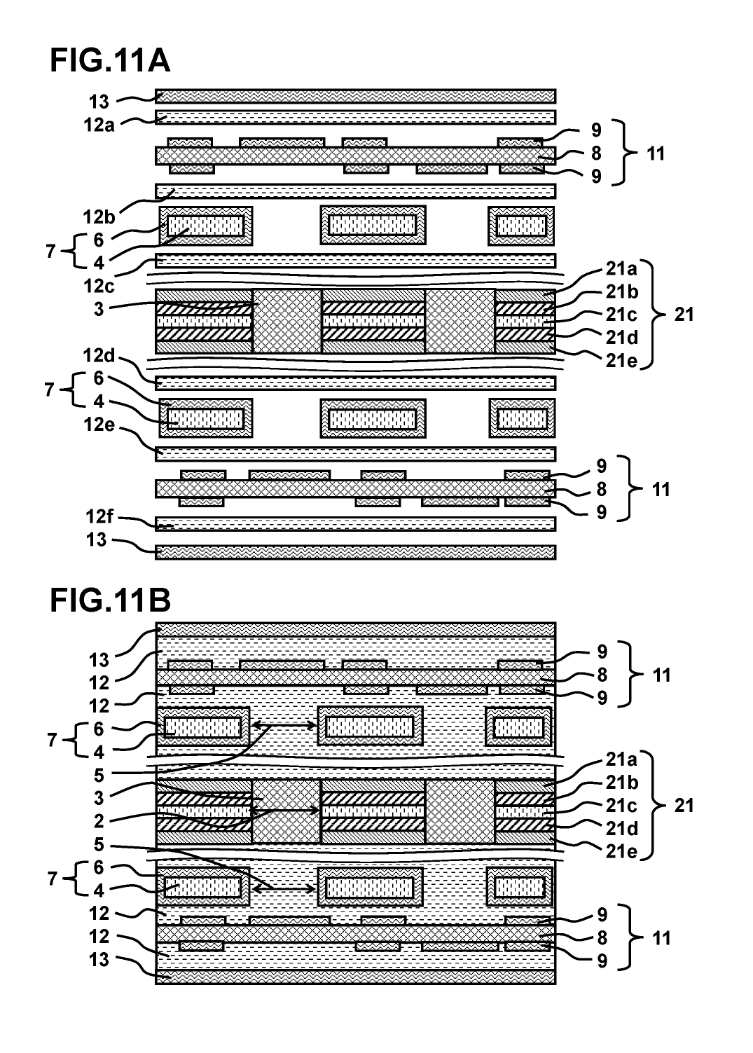

FIG. 11A is a diagram illustrating the state in which a metal foil 13, a prepreg 12a, the second interlayer 11, a prepreg 12b, the first interlayer 7, a prepreg 12c, the core substrate 21, a prepreg 12d, the first interlayer 7, a prepreg 12e, the second interlayer 11, a prepreg 12f, and a metal foil 13 are arranged in this order. The prepregs 12a to 12f are each preferably formed, for example, by impregnating a glass cloth with a thermosetting resin material. The metal foil 13 is preferably formed from copper (Cu).

FIG. 11B is a diagram illustrating a step of forming a laminate in which the core substrate 21, the first interlayers 7 having the lower holes 5, the second interlayers 11, and the metal foils 13 are laminated with the respective prepregs 12 interposed therebetween. The prepregs 12a, 12b, 12c, 12d, 12e, and 12f illustrated in FIG. 11A are cured into the prepregs 12 illustrated in FIG. 11B by a heat treatment. By the step described above, the laminate in which the core substrate 21, the first interlayers 7 having the lower holes 5, the second interlayers 11, and the metal foils 13 are laminated with the respective prepregs 12 interposed therebetween is formed. The lower holes 5 formed beforehand in the first interlayer 7 are filled with the prepregs 12.

In this step, the lower holes 2 of the core substrate 21 are preferably arranged concentrically with the respective lower holes 5 of the first interlayer 7. The reason for this is to prevent penetrating holes 14a from penetrating the core substrate 21 and the first interlayers 7, each of which is a conduction member, when the penetrating holes 14a are formed.

Application of pressure to each member is carried out by a vacuum press (not illustrated). A temperature for pressure application is preferably, for example, 170° C. to 220° C. The prepregs 12a to 12f in an uncured state are formed between the layers and are cured into the prepregs 12 by application of heat and pressure. Then, the core substrate 21, the first interlayers 7, and the second interlayers 11 are laminated to each other with the prepregs 12 interposed therebetween so as to be electrically insulated from each other.

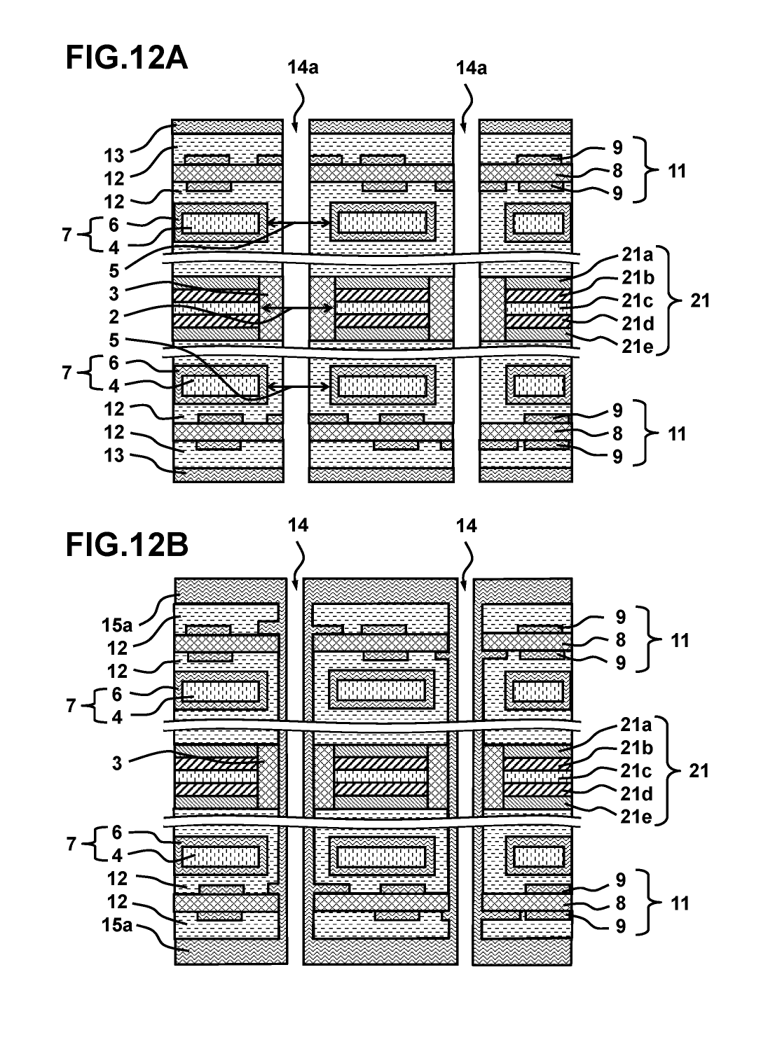

FIG. 12A is a diagram illustrating a step of forming the penetrating holes 14a for forming the through holes 14 in the core substrate 21, the first interlayers 7, and the second interlayers 11 laminated with the prepregs 12 interposed therebetween. The penetrating holes 14a are preferably formed by penetrating the first interlayers 7, the second interlayers 11, and the core substrate 21 in a thickness direction using drill machining. The penetrating holes 14a may be concentric with the lower holes 2 of the core substrate 21 and the lower holes 5 of the first interlayers 7. The penetrating hole 14a is preferably formed to have a diameter, for example, of 200 μm to 400 μm. The penetrating hole 14a is preferably formed so as to have a smaller diameter than that of each of the lower hole 2 of the core substrate 21 and the lower hole 5 of the first interlayer 7. At a portion at which the penetrating hole 14a penetrates the core substrate 21, the insulating resin 3 is exposed to the inner wall surface of the penetrating hole 14a. In addition, at a portion at which the penetrating hole 14a penetrates the first interlayer 7, the prepregs 12 are exposed to the inner wall surface of the penetrating hole 14a.

As in the case illustrated in FIG. 5B, FIG. 12B is a diagram illustrating a step of, after the penetrating holes 14a are formed, performing electroless copper plating and electrolytic copper plating over the substrate. As illustrated in FIG. 12B, a third plating layer 15a is formed all over the entire inner wall surfaces of the penetrating holes 14a and the entire surfaces of the substrate. Then, the through holes 14 are formed along the inner surfaces of the penetrating holes 14a.

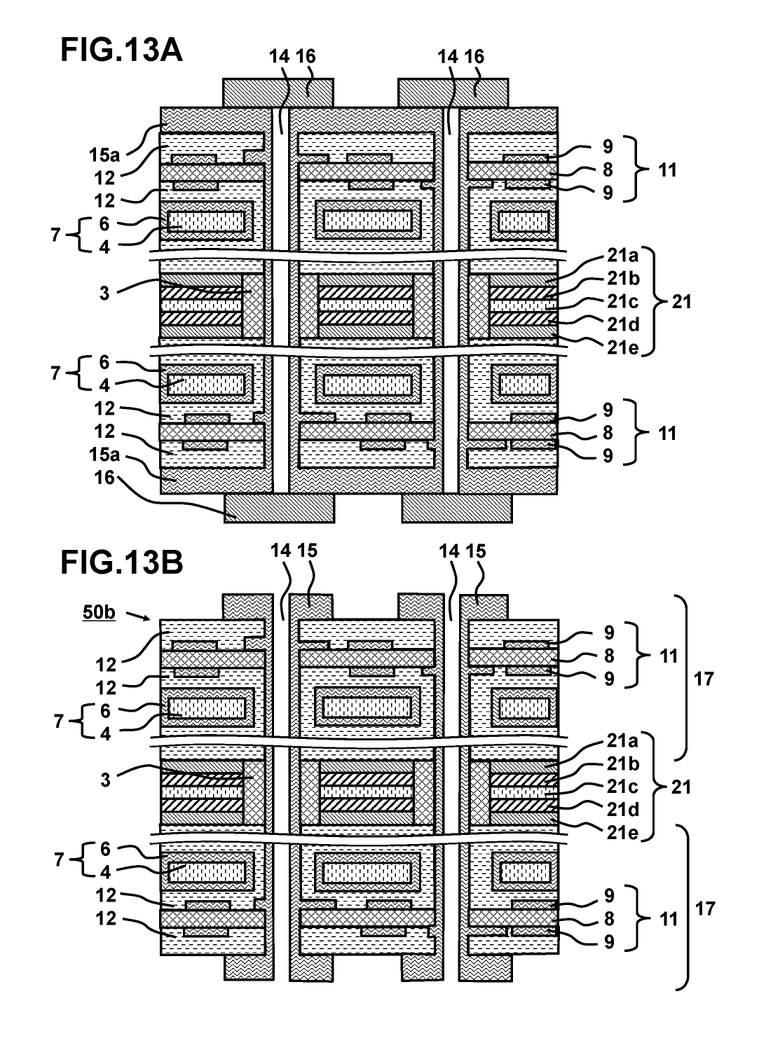

As in the case illustrated in FIG. 6A, FIG. 13A is a diagram illustrating a step of, after a dry film resist (photoresist) (not illustrated) is laminated over the surface of the third plating layer 15a adhered over each surface of the substrate, performing exposure and development over the dry film resist. As illustrated in FIG. 13A, resist patterns 16 are formed over portions at which the third wiring layers 15, which may be described later, are to be formed.

As in the case illustrated in FIG. 6B, FIG. 13B is a diagram illustrating the state in which the third plating layer 15a located at portions at which the resist patterns 16 are not formed is etched off and in which the resist patterns 16 are then peeled off. As illustrated in FIG. 13B, the third wiring layers 15 are formed under the resist patterns 16 by etching the third plating layer 15a. Subsequently, the third wiring layers 15 are exposed at the surfaces of the substrate by peeling off the resist patterns 16 formed over the third wiring layers 15. Through the steps described above, the wiring substrate 50b is formed which includes the core substrate 21 and the wiring layers 17 each formed by laminating the first interlayers 7, the second interlayers 11, and the prepregs 12.

According to the wiring substrate 50b of the second embodiment, as in the case of the wiring substrate 50a according to the first embodiment, carbon fibers and a metal having a high elastic modulus are applied to the core substrate 21. Then, as in the case of the first embodiment, even if the total number of layers of the wiring layer 17 is increased, the amount of displacement caused by thermal expansion of the prepregs 12 may be reduced by the metal plate 4 which forms the first interlayer 7. Therefore, the amount of displacement caused by thermal expansion of the wiring substrate 50b formed by laminating the wiring layers 17 with the core substrate 21 containing a carbon material may be reduced. As a result, fatigue breakage and/or disconnection of the wiring substrate 50b caused by a thermal stress and a thermal strain, which are generated when a semiconductor element is bare-chip mounted over the wiring substrate 50b, may be suppressed.

All examples and conditional language recited herein are intended for pedagogical purposes to aid the reader in understanding the embodiment and the concepts contributed by the inventor to furthering the art, and are to be construed as being without limitation to such specifically recited examples and conditions, nor does the organization of such examples in the specification relate to a illustrating of the superiority and inferiority of the embodiment. Although the embodiments have been described in detail, it should be understood that the various changes, substitutions, and alterations could be made hereto without departing from the spirit and scope of the invention.

What is claimed is:

1. A wiring substrate comprising:
a substrate containing a carbon material;
a first insulating layer formed over the substrate;
an interlayer formed over the first insulating layer, the interlayer including a metal plate having a smaller coefficient of thermal expansion than the first insulating layer while having a greater elastic modulus than the first insulating layer; and
a second insulating layer formed over the interlayer.

2. The wiring substrate according to claim 1, wherein the interlayer further includes a first conductive layer formed over the metal plate.

3. The wiring substrate according to claim 1, further comprising:
a second conductive layer formed over the second insulating layer; and
a third insulating layer formed over the second conductive layer.

4. The wiring substrate according to claim 1, wherein the carbon material is carbon fiber or carbon nanotube.

5. The wiring substrate according to claim 1, wherein the substrate further includes a metal plate containing at least one of an Invar (iron-nickel) alloy, a Kovar (iron-nickel-cobalt) alloy, Alloy 42 (iron-nickel), tungsten and molybdenum.

6. The wiring substrate according to claim 1, wherein the metal plate contains at least one of an Invar (iron-nickel) alloy, a Kovar (iron-nickel-cobalt) alloy, Alloy 42 (iron-nickel), tungsten, and molybdenum.

7. A method for manufacturing a wiring substrate, comprising:
forming a substrate containing a carbon material;
forming a first insulating layer over the substrate;
forming an interlayer over the first insulating layer, the interlayer including a metal plate having a smaller coefficient of thermal expansion than the first insulating layer while having a greater elastic modulus than the first insulating layer; and
forming a second insulating layer over the interlayer.

8. The method according to claim 7, further comprising forming a first conductive layer over the metal plate.

9. The method according to claim 7, further comprising:
forming a second conductive layer over the second insulating layer; and
forming a third insulating layer over the second conductive layer.

10. The method according to claim 7, wherein the carbon material is carbon fiber or carbon nanotube.

11. The method according to claim 7, wherein the substrate further includes a metal plate containing at least one of an Invar (iron-nickel) alloy, a Kovar (iron-nickel-cobalt) alloy, Alloy 42 (iron-nickel), tungsten, and molybdenum.

12. The method according to claim 7, wherein the metal plate contains at least one of an Invar (iron-nickel) alloy, a Kovar (iron-nickel-cobalt) alloy, Alloy 42 (iron-nickel), tungsten, and molybdenum.
